(19) United States
(12) Patent Application Publication
(10) Pub. No.: US 2003/0178682 A1
(43) Pub. Date: Sep. 25, 2003

(54) Semiconductor device and method of manufacturing the semiconductor device

(76) Inventors: Takeshi Noda, Kanagawa (JP); Tatsuya Arao, Kanagawa (JP); Aiko Shiga, Kanagawa (JP); Hidekazu Miyairi, Kanagawa (JP); Masayuki Kajiwara, Tochigi (JP)

Correspondence Address: ERIC ROBINSON, PMB 955, 21010 SOUTHBANK ST., POTOMAC FALLS, VA, 20165, US

(21) Appl. No.: 10/324,066

(22) Filed: Dec. 20, 2002

(30) Foreign Application Priority Data
Dec. 28, 2001 (JP) 2001-399287

(51) Int. Cl. H01L 29/76; H01L 29/94; H01L 31/062; H01L 31/113; H01L 31/119

(52) U.S. Cl. 257/368

(57) ABSTRACT

An object is to form a crystalline semiconductor film having good crystallinity by applying a CW laser thereto, and to achieve a TFT capable of very high speed operation by using the semiconductor film thus obtained. A p-type impurity element is added to crystalline silicon (semiconductor layer), which has a film thickness of 60 to 400 nm and is formed by using a CW laser, in particular, to a channel formation region in a region that becomes an n-channel TFT. The p-type impurity element is added at an acceleration energy of 30 to 120 keV so that its concentration becomes 1×10¹⁵ to 5×10¹⁸ /cm³.

### BACKGROUND OF THE INVENTION

1. Field of the Invention

The present invention relates to semiconductor device with a crystalline semiconductor film, for example, a semiconductor device with a transistor, particularly a field effect type transistor, typically a MOS (metal oxide semiconductor) transistor or a thin film transistor (TFT), and to a method of manufacturing the same.

2. Description of the Related Art

In order to realize TFTs for forming a circuit that is capable of high-speed operation and that can process an enormous amount of information while achieving a field effect mobility higher than that of amorphous silicon, studies on methods of forming polycrystalline silicon (also called polysilicon) of high quality at a lower temperature on an inexpensive glass substrate have been actively advancing.

Since the polycrystalline silicon is formed on a glass substrate with a low distortion point, it is necessary that processing can be performed at a low temperature. Thus, compared to methods using a furnace, a method of irradiating a laser light (hereinafter referred to as laser annealing method) with which processing can be performed at a low temperature and which has high throughput and productivity is attracting attention.

Further, compared to annealing methods using radiation heating or conduction heating, laser light annealing methods that are characterized by significantly reducing the processing time and heating a semiconductor or a semiconductor film selectively or locally so that thermal damage is hardly applied on a substrate are considered suitable in the case of manufacturing by using a large-sized glass substrate for a large-sized display device or the like or in the case of mass production. Thus, technical development of the laser light annealing methods is actively advancing.

Among them, in particular, a crystallization method that is performed by irradiating solid continuous wave lasers (specifically, lasers such as Nd:YAG lasers and Nd:YVO₄ lasers. hereinafter referred to as CW lasers) has gained high appraisal because with this method, it is possible to form a crystalline silicon film with a large grain size and a high field effect mobility.

The amount of time that a semiconductor film is heated by laser light is long when performing crystallization by using a CW laser, compared to processing by a pulse laser such as an excimer laser. Portions of the film to which the laser light is irradiated melt completely, and crystal growth proceeds in a direction in which an interface between a melted region and a solid phase region is nearly parallel to a substrate (hereinafter referred to as horizontal direction crystal growth). At this time, heat due to CW laser irradiation quickly escapes from an amorphous silicon film to a substrate side if the initial film thickness of the amorphous silicon film is thin, and solidification by cooling is fast. Crystal nuclei naturally develop in the vicinity of the easily cooled substrate before horizontal direction crystal growth, and this causes a problem in that crystal grains having a large grain size cannot be obtained. There is also a problem in that the semiconductor film is peeled off during the irradiation of laser light for crystallization, and damage may be imparted to a base insulating film.

Further, although there are conditions at which it is possible to perform crystallization without causing the film to peel off, even if the film thickness is thin (specifically, equal to or less than 60 nm), the conditions involve a problem in that the range (margin) in which these conditions (laser power) are usable is narrow. An example in which the film is actually peeled off and a formed silicon film disappears is shown in FIG. 1 (under the following conditions: Nd:YVO₄ laser, wavelength of 532 nm, laser power of 6.7 W, and scanning speed of 50 cm/sec).

In order to solve the problem in that the film is peeled off during crystallization processing performed by using CW laser irradiation as shown in FIG. 1, and the problem in that the laser light irradiation condition margin is narrow during laser light irradiation processing which takes place during crystallization, the thickness of the semiconductor film is set equal to or greater than 60 nm, and thicker than that employed when using a pulse oscillation laser, and crystallization is performed by using a CW laser. A semiconductor film capable of achieving a large grain size and a high field effect mobility is thus formed.

On the other hand, although crystals having large grain size (in which high field effect mobility is obtained) can be realized when forming TFTs after making a semiconductor film thicker, a problem in that a leak current flowing when the TFT is off (also referred to as an off current and an off leak current) becomes larger has still not been solved.

The following factors are considered as causes for the increased leak current.

A first cause is that, in a state where a gate voltage is not applied, carriers having the same polarity as a source region and a drain region exist in a channel formation region. Specifically, carriers are not completely removed toward the source region side, where the influence of the gate voltage does not extend, due to the film thickness of a semiconductor layer, and a region develops in which the carriers collect.

For example, if −10 V is applied from a gate electrode as a negative voltage, and 1 V is applied to a drain electrode as a positive voltage, then the carriers accumulate in the vicinity of an interface between the semiconductor layer and a gate insulating film. The carrier is removed to the source region by the influence of the gate voltage. However, if the film thickness of the semiconductor layer becomes thicker, then the gate voltage does not exert influence on a deep region away from the gate electrode, removal of the carrier becomes impossible, and the carriers collect there. This region at which the carriers have collected causes the leak current.

Results of a simulation as to the relationship between the film thickness of the semiconductor layer and the cause of the increased leak current are shown in FIGS. 2 to 5.

The content of the simulation is explained here. The simulation is performed on a TFT having a general shape, in which a gate insulating film is formed on a semiconductor layer, and a gate electrode is formed on the gate insulating film. The results of the simulation are shown when it is performed on four types of TFTs respectively having film thicknesses of the semiconductor layer of 60 nm (FIG. 2), 80 nm (FIG. 3), 100 nm (FIG. 4), and 150 nm (FIG. 5). Note that polysilicon is generally assumed to be of weak n-type conductivity, and therefore the simulations are performed assuming that each of the silicon films having the above film thicknesses is of weak n-type conductivity. Further, it is assumed that −10 V is applied to the gate electrode, 1 V is applied to a drain electrode, and 0 V is applied to a source electrode. FIGS. 2 to 5 are graphs showing the relationship between the charge density of a region corresponding to a channel formation region of the semiconductor layer of the TFT (vertical axis) and depth thereof (horizontal axis).

First, the left edge side of the graphs is in the vicinity of a surface of the semiconductor layer (interface with the gate insulating film), and this area is influenced by the voltage of −10 V applied to the gate electrode. Holes (positive charge) accumulate there.

Provided next is a region having the charge of silicon itself originally having weak n-type conductivity (+charge), which is influenced by the gate voltage and in which the carrier (− charge) is removed to the source side. Note that the charge existing in this region is a fixed charge, and therefore it does not contribute to electrical conduction. This type of region is referred to as a depletion layer.

The gate voltage exerts influence from the surface to the lowest portion when the silicon film thickness is 60 nm, and therefore carriers are removed and do not accumulate (this is referred to as complete depletion). However, if the silicon film thickness becomes thicker, then a region develops, in which the gate voltage does not exert influence (a deep region having a depth from the surface equal to or greater than 60 nm). There is no influence exerted by the gate voltage, and therefore a region develops in which the carriers (negative charges) accumulate below a region in the channel formation region through which the carrier passes (this is referred to as partial depletion). A region thus develops in which there is no influence from the gate voltage, and the carriers (negative charges) accumulate. This becomes a path through which the carrier passes (referred to as a back channel), and causes the leak current to develop when the TFT is off.

The second cause can be considered as follows. Current flowing in the channel formation region is normally controlled by the gate voltage. In this case, as shown in FIGS. 2 to 5, the depletion layer in the vicinity of the interface of the channel formation region with the gate insulating film is formed roughly parallel to a surface of the channel formation region (substrate surface), and a uniform electric field is formed.

However, if a drain voltage is applied, and the value of the drain voltage becomes high, then the depletion layer is formed in order to terminate the drain voltage. With the demand in recent years for highly integrated semiconductor devices made as miniature as possible as a background, if the gate length becomes short and the distance between the drain region and the source region becomes short, then the depletion layer generated in the periphery of the drain region is expanded and reaches the periphery of the source region, and it becomes impossible to control the current between source and the drain by using the gate voltage. As a result, this causes a leak current to develop (a state in which current flows between the source and the drain).

From the above simulation results, the inventors of the present invention infer that if the film thickness of the semiconductor layer is 60 nm or greater, this involves a state in which leak currents easily develop due to the development of back channels and due to the depletion layer in the periphery of the drain region, caused by applying a drain voltage, expanding and reaching the source region (punch-through phenomenon).

### SUMMARY OF THE INVENTION

In order to solve the above problems, an objet of the present invention is to provide a semiconductor device in which crystal grain size can be made larger by using a CW laser, and in which leak currents can be suppressed, even if a semiconductor film having a thick film thickness which is capable of achieving a high field effect mobility is used. In addition, another object of the present invention is to provide a method of manufacturing the semiconductor device.

Further, another object of the present invention is to provide a semiconductor device capable of very high speed operation, in which a crystalline semiconductor film of good quality is formed by applying a CW laser thereto and the semiconductor film thus obtained is used, and a method of manufacturing the semiconductor device.

The present invention is characterized in that an impurity element is added to a channel formation region at a concentration of 1×10¹⁵ to 5×10¹⁸/cm³ in order to control leak current caused by punch-through phenomenon or by formation of a back channel which becomes a problem in forming semiconductor films (silicon films) at a film thickness of 60 to 200 nm by applying a CW laser thereto.

From the above simulation results, the inventors of the present invention found that the development of back channels and the expansion of depletion layers can be suppressed by adding an impurity element that imparts p-type conductivity to a portion which becomes a channel formation region of a semiconductor layer, even in n-channel TFTs formed by using crystalline silicon having a film thickness equal to or greater than 100 nm and crystallized by applying a CW laser thereto.

Further, the formation of back channels occurs when the film thickness of the semiconductor film is equal to or greater than 60 nm, and therefore the following is found: expansion of depletion layers can be suppressed, the off current can be controlled so as not to increase, and a TFT having good characteristics can be realized by forming a region, into which a p-type impurity element is added, at a depth equal to or greater than 60 nm from a surface of a semiconductor layer.

The present invention is characterized in that a p-type impurity element is added to a channel formation region, in particular a region which becomes an n-channel TFT, in crystalline silicon (semiconductor layer) having a film thickness of 60 to 200 nm and formed by using a CW laser. The p-type impurity element is added at a concentration of 1×10¹⁵ to 5×10¹⁸/cm³ by using an acceleration energy of 30 to 120 keV.

Further, the present invention is characterized in that, in particular there is a region for controlling the depletion layer expansion, in which a p-type impurity element is added so that a region of concentration peak of a p-type impurity element is formed at a depth equal to or greater than 60 nm from a surface of a semiconductor layer.

Depletion layer expansion can be suppressed, and leak currents flowing when a TFT is off can be reduced due to an influence of an applied impurity element, by applying the present invention (for example, adding an impurity element that imparts p-type conductivity to a channel formation region of an n-channel TFT) in cases where the film thickness of a silicon film is made large, i.e., equal to or greater than 100 nm, for example, with the objectives of 1) preventing a film from peeling off, and 2) expanding the margin of the irradiation conditions, when irradiating a CW laser to form a crystalline semiconductor film having a large crystal grain size (specifically, a crystalline silicon film). Further, leak currents due to back channel formation which flow when a TFT is off can also be suppressed.

### BRIEF DESCRIPTION OF THE DRAWINGS

In the accompanying drawings:

FIG. 1 is a diagram for observing peeling of a film in a silicon film to which a CW laser has been irradiated;

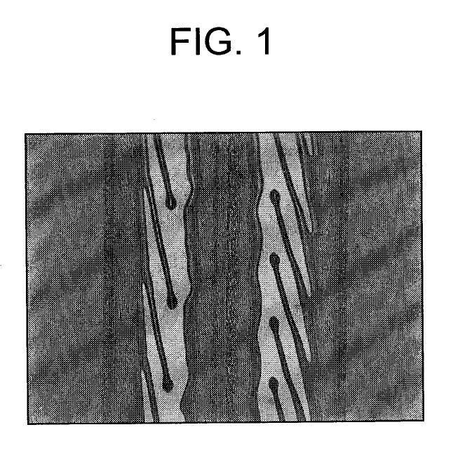

FIG. 2 is a diagram showing simulation results for a case in which the thickness of a silicon film is 60 nm;

FIG. 3 is a diagram showing simulation results for a case in which the thickness of a silicon film is 80 nm;

FIG. 4 is a diagram showing simulation results for a case in which the thickness of a silicon film is 100 nm;

FIG. 5 is a diagram showing simulation results for a case in which the thickness of a silicon film is 150 nm;

FIG. 6 is a diagram showing simulation results for a relationship between TFT characteristics and the depth of a region of peak impurity element concentration;

FIG. 7 is a diagram showing an Id-Vg curve for a TFT in which the thickness of a silicon film is 54 nm;

FIG. 8 is a diagram showing an Id-Vg curve for a TFT in which the thickness of a silicon film is 170 nm, and which is manufactured at an acceleration energy of 15 keV when performing channel doping;

FIG. 9 is a diagram showing an Id-Vg curve for a TFT in which the thickness of a silicon film is 170 nm, and which is manufactured at an acceleration energy of 60 keV when performing channel doping;

FIGS. 10A to 10D are diagrams showing an embodiment mode of the present invention;

FIGS. 11A to 11C are diagrams showing an embodiment mode of the present invention;

FIGS. 12A to 12C are diagrams showing an embodiment mode of the present invention;

FIGS. 13A and 13B are diagrams showing an embodiment mode of the present invention;

FIG. 14 is a diagram showing an embodiment mode of the present invention;

FIGS. 15A to 15D are diagrams showing an embodiment mode of the present invention;

FIGS. 16A to 16F are diagrams showing examples of electrical appliances;

FIGS. 17A to 17D are diagrams showing examples of electrical appliances;

FIGS. 18A to 18C are diagrams showing examples of electrical appliances;

FIG. 19 is a diagram showing absorptivity by silicon of light having a wavelength of 532 nm; and

FIG. 20 is a diagram showing impurity concentration distribution in a depth direction.

### DETAILED DESCRIPTION OF THE PREFERRED EMBODIMENTS

### Embodiment Mode 1

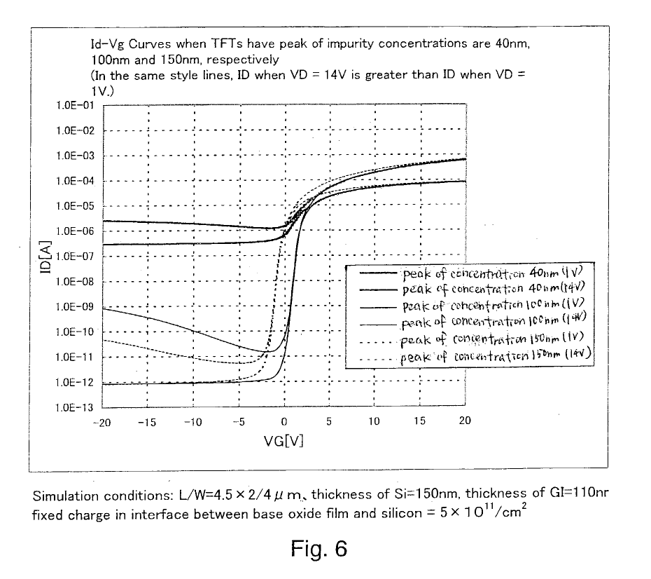

The inventors of the present invention performed simulations regarding Id-Vg characteristics for a TFT in which the length in a channel length direction of a semiconductor layer is taken as L, the length (width) in a direction normal to the channel length direction is taken as W, L/W=(4.5×2)/4, the film thickness of the semiconductor (silicon) layer is 150 nm, and the film thickness of a gate insulating film is 110 nm. A fixed charge on the semiconductor layer is taken as 5×10¹¹/cm², a drain voltage is set to 1 V and 14 V, and a gate voltage is set to −20 V to +20 V when applied. Results from the simulation are shown in FIG. 6.

Cases in which the concentration peak of an impurity element appears in regions of 40 nm, 100 nm, and 150 nm in a depth direction of the semiconductor (silicon) layer are assumed for the simulations, and the Id-Vg characteristics for cases in which the TFT is applied with the drain voltage of 1 V and 14 V, and with the gate voltage of −20 V to +20 V are compared.

From the results of FIG. 6, it can be seen that a leak current flowing when the TFT is off can be suppressed by the addition of the impurity element. In particular, it can be seen that the leak current flowing when the TFT is off can be suppressed for the TFT having a concentration peak for the impurity element in a deep region as seen form a surface of the semiconductor layer (interface with the gate insulating film), and well for the TFT having an impurity element concentration peak in a 100 nm-depth region, and even better for the TFT having an impurity element concentration peak in a 150 nm-depth region.

In order to obtain the impurity element concentration peak in a very deep region as seen from the surface of the semiconductor layer (interface with the gate insulating film), the acceleration energy may be made high (specifically, from 30 to 120 keV) when adding the impurity element.

### Embodiment Mode 2

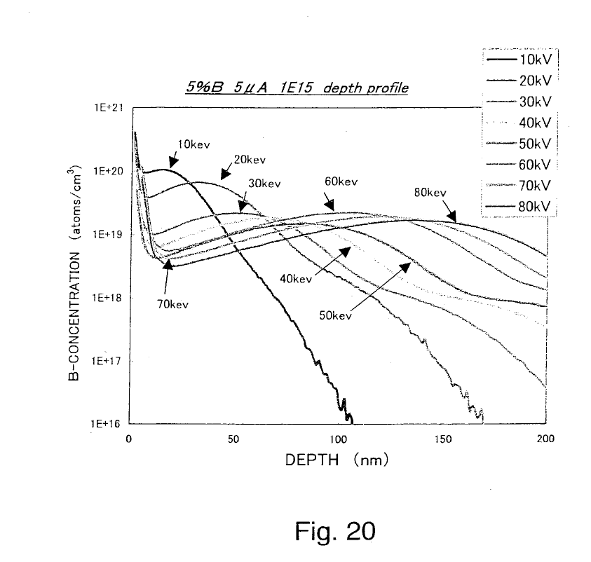

FIG. 20 shows impurity concentration distributions in a depth direction for different acceleration energies. FIG. 20 is a diagram of the results obtained when measuring changes in concentration, with respect to the depth direction, of a p-type impurity element introduced by using ion shower doping. The addition is performed with the acceleration energy set form 10 keV to 80 keV, in 10 keV steps. Note that, although measurements are only performed up to 80 keV because the upper limit of acceleration energy of the apparatus used in this experiment is 80 keV, it is thought that it is possible to use acceleration energies as high as 120 keV using another apparatus.

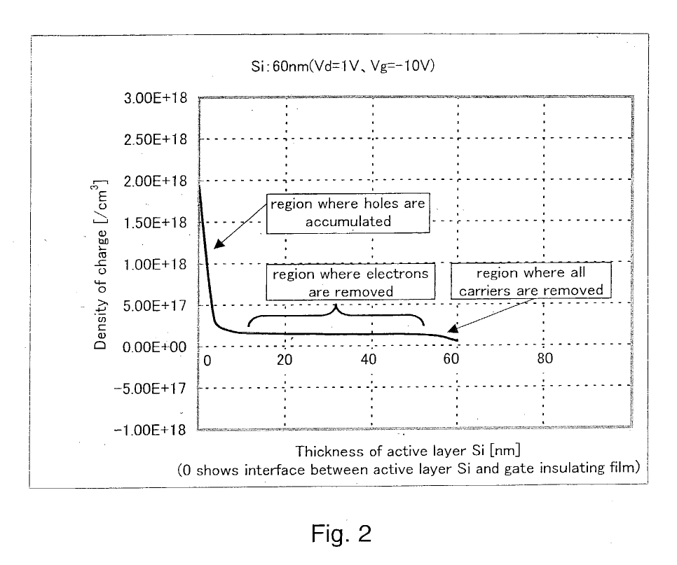

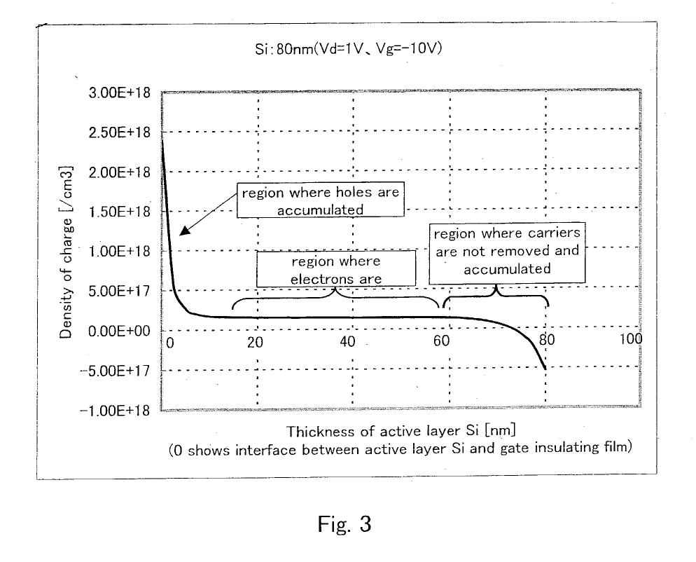

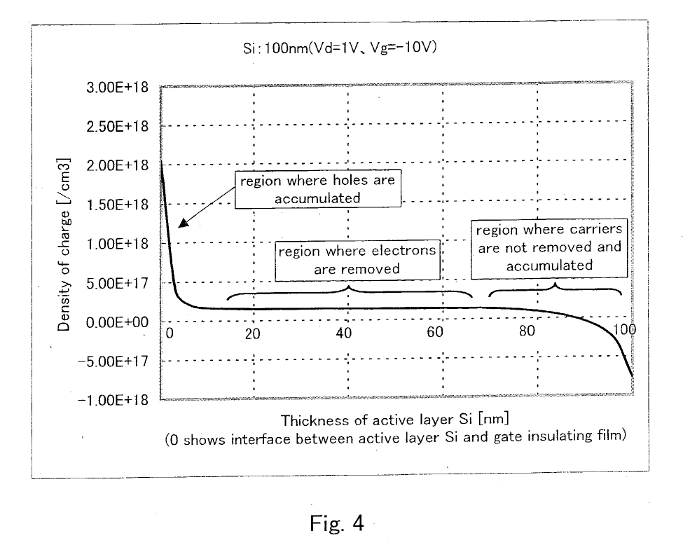

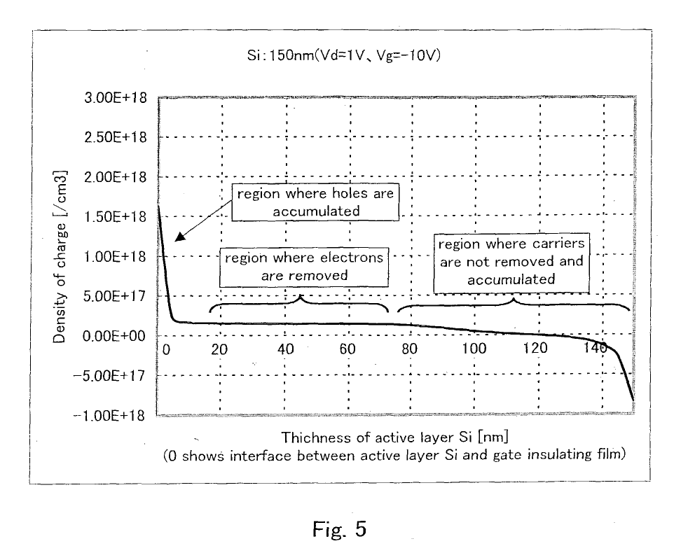

From the simulation results of FIGS. 2 to 5, it is necessary that a peak in the impurity concentration exists at a depth equal to or greater than 60 nm from the semiconductor layer surface with the present invention. It can be seen from FIG. 20 that the existence of the impurity concentration peak at a depth equal to or greater than 60 nm from the semiconductor layer surface can be accomplished under these conditions at an acceleration energy equal to or greater than 30 keV. The acceleration energy depends upon the usage conditions, the desired impurity element to be introduced, its concentration, gas, film thickness, and the like, and users may select a suitable acceleration energy after acquiring similar data.

### Embodiment Mode 3

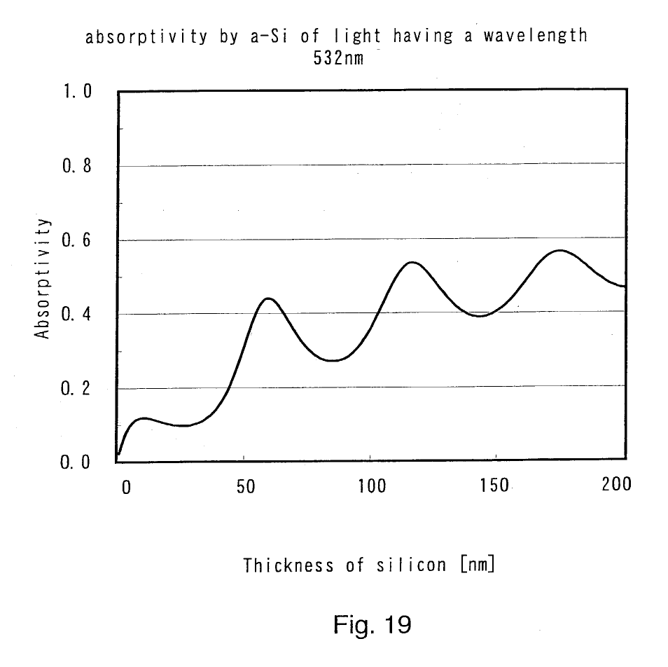

FIG. 19 shows a state in which the absorptivity of light having a wavelength of 532 nm changes with film thickness for a silicon film (amorphous silicon film) formed on a base insulating film (laminate of a 50 nm-thick SiON film and a 100 nm-thick SiNO film), which is formed on a glass substrate.

The absorptivity of the silicon film with respect to light (wavelength: 532 nm) has a periodic peak in accordance with its film thickness. For example, a first peak shows an absorptivity of approximately 0.45 when the film thickness is approximately 60 nm, a second peak shows an absorptivity of approximately 0.5 when the film thickness is approximately 110 nm, and a third peak shows an absorptivity of approximately 0.55 when the film thickness is approximately 170 nm.

The absorptivity of light having a wavelength of 532 nm thus changes in accordance with the film thickness of silicon. Thus, it is very essential to optimize the silicon film to thickness in forming a suitable (large grain size) crystalline silicon film in which the amount of surface area capable of undergoing crystallization processing per unit time, that is, throughput can be increased.

Further, the amount of change in the absorptivity of the silicon film is little in portions having little change (gradient) in absorptivity in FIG. 19, specifically the first peak, the second peak, a portion between the first peak and the second peak, the third peak, or a portion between the second peak and the third peak. The energy absorbed by the silicon film is therefore stable, and uniform crystallization processing can be performed by selecting a film thickness in a region in which the amount of change in absorptivity is small.

Silicon films thus have periodic absorptivity peaks with respect to light having a wavelength of 532 nm, which depend on the film thickness thereof, for cases in which a CW laser is applied in making the film thickness of the silicon films thicker in order to prevent silicon film from peeling off. Silicon can therefore be melted, forming a melted phase, by suitably selecting the film thickness when forming the silicon film. An interface between the melted phase and a solid phase can be moved continuously, thus forming a crystalline semiconductor film (crystalline silicon film) having large size crystal grains.

However, a problem develops in that a leak current like that described above becomes larger if the silicon film thickness is made larger than necessary. It is therefore not preferable to make the film thickness larger than necessary. Considering the above discussion, it is preferable that the silicon film thickness (in a channel formation region) be from 60 to 200 nm.

The Id-Vg characteristics for n-channel TFTs formed using crystalline silicon, which is crystallized by CW laser irradiation, having film thicknesses of 54 nm and 170 nm are compared. Note that the conditions for crystallization for the TFT having the 54 nm-thick silicon film by using a CW laser are a power of 2.5 W, a scanning speed of 50 cm/sec, and in adding boron as a p-type impurity element to a channel formation region, a dosage of 4×10¹²/cm² and an acceleration energy of 15 keV. Further, there are two TFTs having a silicon film thickness of 170 nm. The conditions for crystallization for one TFT having the 170 nm-thick silicon film by using a CW laser are a power of 3.6 W, a scanning speed of 50 cm/sec, and in adding boron as a p-type impurity element to a channel formation region, a dosage of 1×10¹⁴/cm² and an acceleration energy of 60 keV. The conditions for crystallization for the other TFT having the 170 nm-thick silicon film by using a CW laser are a power of 3.6 W, a scanning speed of 50 cm/sec, and in adding boron as a p-type impurity element to a channel formation region, a dosage of 8×10¹²/cm² and an acceleration energy of 15 keV. The Id-Vg characteristics of three types of TFTs are thus compared.

Note that the conditions for measuring the Id-Vg characteristics for the above-mentioned three types of TFTs are a source voltage Vs of 0 V, a drain voltage Vd of 1 V or 5 V, and a gate voltage Vg that is changed from −14 V to 14 V. Further, a TFT channel length L is 6 μm, and a channel width W is 4 μm.

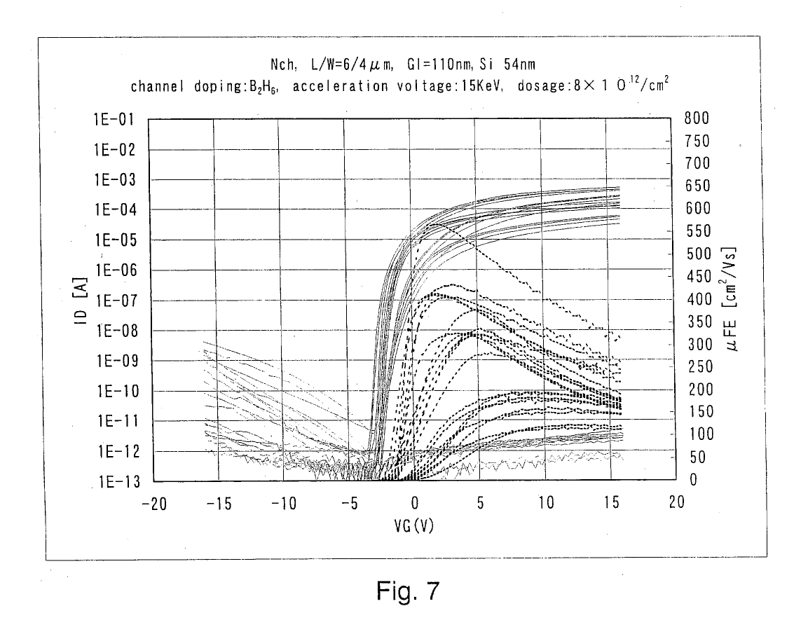

First, the Id-Vg characteristics for the TFT having the 54 nm-thick semiconductor layer are shown in FIG. 7. The field effect mobility of the semiconductor layer (μ max) is 566.0 cm²/Vs, with a standard deviation of 149.9, and thus a large dispersion. Further, the average value of the leak current when the TFT is off is 65.4 μA.

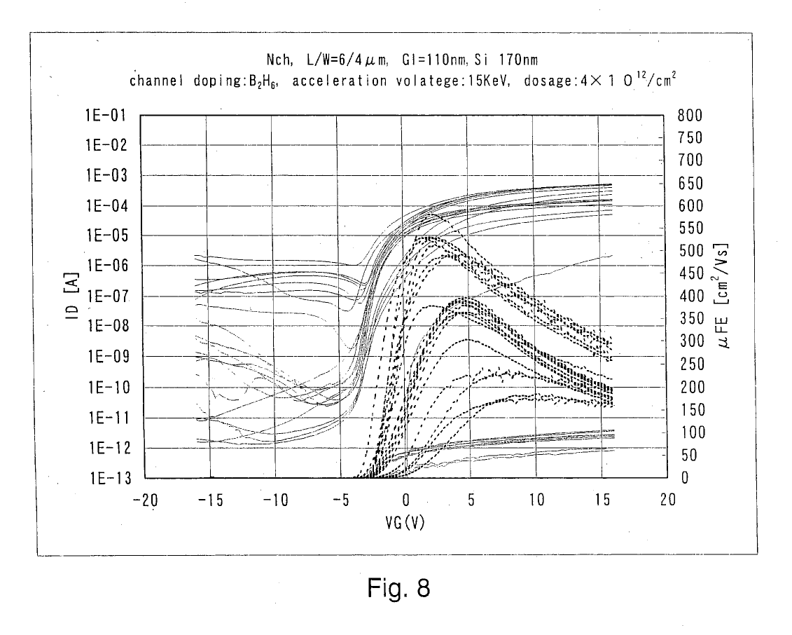

Next, FIG. 8 shows the Id-Vg characteristics for the TFT having the 170 nm-thick semiconductor layer, in which a region containing a p-type impurity element at a concentration of 1×10¹⁵ to 5×10¹⁸/cm³ is formed in the channel formation region at a low acceleration energy (15 keV). This semiconductor layer had a field effect mobility (μmax) of 580.6 cm²/Vs, with a standard deviation of 135.6, and thus a large dispersion. Further, the current on the left edge side of the graph in FIG. 8 (when the TFT is off) is large, and a leak current develops. It can be seen that the average value of the leak current is high at 94.7 μA.

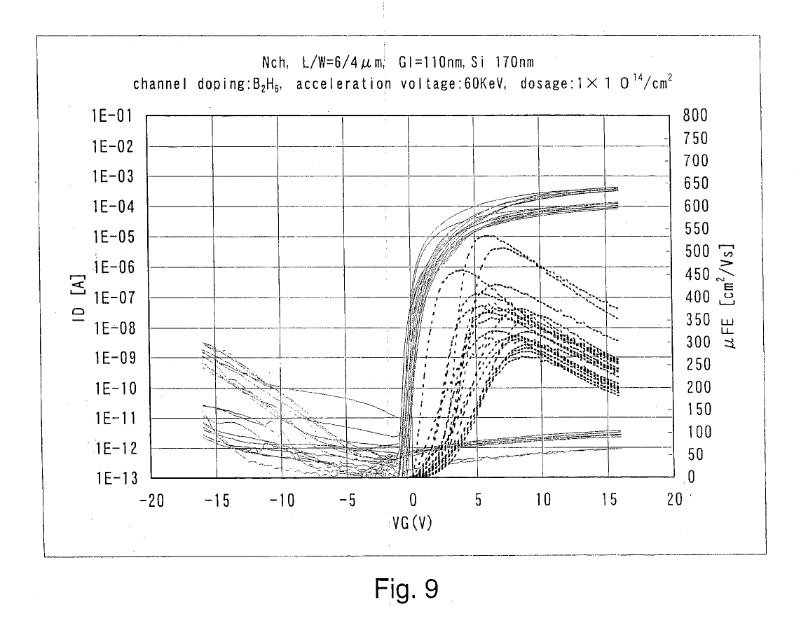

Based on the above experimental results, FIG. 9 shows the Id-Vg characteristics for the TFT having the 170 nm-thick semiconductor layer in accordance with the present invention, in which a region containing a p-type impurity element at a concentration of 1×10¹⁵ to 5×10¹⁸/cm³ is formed in the channel formation region at a high acceleration energy (60 keV). It can be seen that this semiconductor layer had a field effect mobility (μ max) of 534.6 cm²/Vs, with a standard deviation of 69.5, and the dispersion thus became smaller. Further, the average value for the current in the left edge side of the graph of FIG. 9 (when the TFT is off) is 62.3 μA, which is low compared to the TFTs having a 170 nm-thick semiconductor layer, to which channel doping is performed at a low acceleration energy. It can therefore be seen that the leak current can be suppressed to a level having almost no difference with the 54 nm-thick semiconductor layer TFT, for which it can be considered that back channels are not formed.

As shown by the above results of measuring the Id-Vg characteristics, a semiconductor device (TFT) having good characteristics with a reduced leak current can be achieved by forming a region containing a p-type impurity element at a concentration of 1×10¹⁵ to 5×10¹⁸/cm³ in a channel formation region, even if the film thickness is made thick, in a TFT manufactured using a silicon film crystallized by using a CW laser.

### Embodiment Mode 4

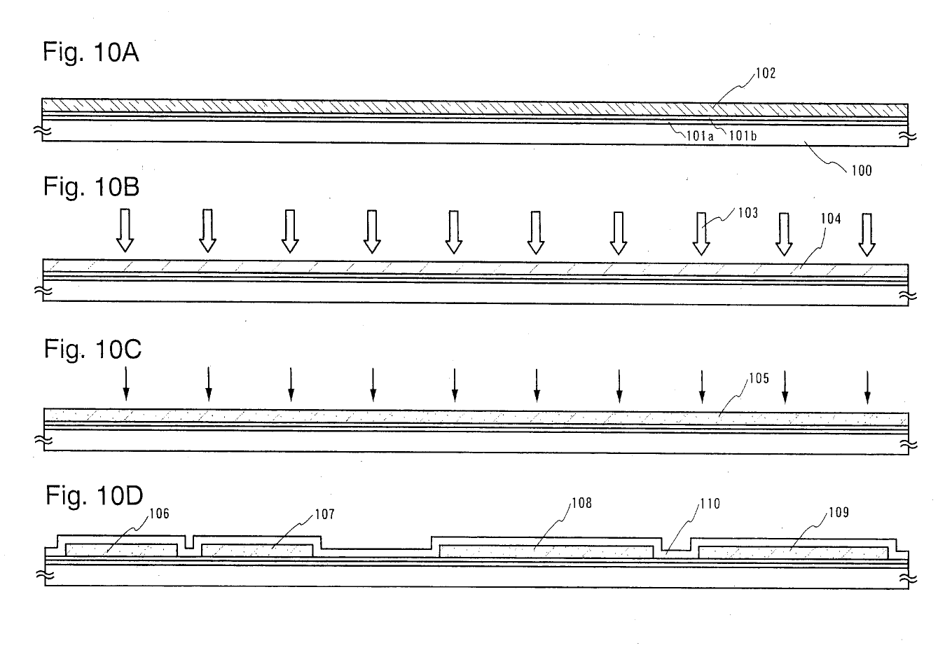

An example of a technique for manufacturing a semiconductor device by applying the present invention is explained using FIGS. 10A to 14.

A base insulating film 101 is formed on a substrate 100. A commercially available non-alkaline glass substrate such as aluminoborosilicate glass is applied as the substrate 100. It is preferable to form the base insulating film 101 by using a silicon oxynitride film. A silicon oxynitride film formed by using SiH₄, NH₃, and N₂O, and a silicon oxynitride film formed by using SiH₄ and N₂O are formed here having film thicknesses of 50 nm and 100 nm, respectively, making a structure provided with the ability of preventing diffusion of impurities from the glass substrate 100 and of relieving stress.

A silicon film 102 having a film thickness on the order of 60 to 200 nm is then formed by a known means (such as sputtering, LPCVD, or plasma CVD) on the base insulating film 101 as a semiconductor film. Note that the semiconductor film may be an amorphous semiconductor film, a microcrystalline semiconductor film, or a crystalline semiconductor film (see FIG. 10A).

Heat treatment is then performed prior to crystallization at a temperature of 400 to 500° C. for on the order of one hour, thus driving out hydrogen from within the film. Heat treatment is performed for one hour at 500° C. in a furnace in Embodiment Mode 4.

Continuous wave laser light 103 is then irradiated to the silicon film 102, melting the silicon film and forming a melted phase. An interface between the melted phase and a solid phase is moved continuously by scanning the irradiation position of the laser light 103, thus forming a crystalline silicon film 104. Crystal growth advances by this process so that crystal grains extend in the laser light scanning direction (see FIG. 10B).

A gaseous laser oscillating apparatus or a solid laser oscillating apparatus is applied as the laser oscillating apparatus, and in particular, a laser oscillating apparatus capable of continuous oscillation is used. Laser oscillating apparatuses using crystals such as YAG, YVO₄, YLF, or YAlO₃, into which Cr, Nd, Er, Ho, Ce, Co, Ti, or Tm is doped, may be applied as a continuous wave solid laser oscillating apparatus. The fundamental wave of the oscillation wavelength differs depending on the material used in doping, but oscillation is achieved at wavelengths from 1 μm to 2 μm. A diode excitation solid laser oscillating apparatus may be applied in order to obtain a very high output, and such apparatuses may also be given a cascade connection.

Note that, in the present invention, optical system of laser irradiation disclosed in U.S. Patent Laid-open No. 2001/0021544A1 may be used.

Typical examples of solid lasers used in crystallizing a semiconductor film, and the wavelengths of their second harmonics, are shown here. The wavelength for an Nd:YAG laser is 532 nm, the wavelength for an Nd:YVO₄ laser is 532 nm, the wavelength for an Nd:YLF laser is 527 nm or 524 nm, the wavelength for a Ti:sapphire laser is from 345 to 550 nm (variable), and the wavelength for an alexandrite laser is from 350 to 410 nm (variable).

Laser light for crystallizing the amorphous semiconductor film is selectively absorbed by the semiconductor film in Embodiment Mode 4, and therefore laser light having a wavelength in the visible region is applied, and the second harmonic of the fundamental wave is used. A wavelength converter element (SHG) is used in order to obtain the second harmonic. ADP (ammonium dihydrogen phosphate), Ba₂NaNb₅O₁₅ (barium-sodium niobate), CdSe (cadmium selenide), KDP (potassium dihydrogen phosphate), LiNbO₃ (lithium niobate), Se, Te, LBO, BBO, KB5, and the like can be applied as the wavelength converter element. In particular, it is preferable to use LBO. The second harmonic (532 nm) of an Nd:YVO₄ laser oscillating apparatus (fundamental wavelength: 1064 nm) is typically used when crystallizing the amorphous semiconductor film. Further, the laser oscillation mode applies a single mode, which is a TEM00 mode.

Note that the laser light may be scanned by back and forth scanning, as well as scanning in a single direction. It is possible to change the laser energy density for each single scanning when employing back and forth scanning, and to cause stepwise crystal growth. Further, it is also possible to perform dehydrogenation processing, which often becomes necessary when crystallizing amorphous silicon films, at the same time. Scanning may be performed initially at a low energy density, and then the energy density may be increased after hydrogen has been driven out, thus accomplishing crystallization with the second scanning. A crystalline silicon film having crystal grains extending in the scanning direction of the laser light can also be obtained similarly by using this type of manufacturing method.

A p-type impurity element is then added to a semiconductor layer, in particular to a region which later becomes a channel formation region. Specifically, the p-type impurity element is added so that a concentration peak exists in a region at a depth equal to or greater than 60 nm from a surface of the semiconductor layer (later the channel formation region). Boron (B) may be added, for example, as the p-type impurity element using ion shower doping at an acceleration energy of 30 to 120 keV, so that the actual p-type impurity element concentration within silicon becomes 1×10¹⁵ to 5×10¹⁸/cm³ (see FIG. 10C). Note that, although the impurity element is added in Embodiment Mode 4 by using ion shower doping, ion injection may also be applied as another method of adding the impurity element.

The impurity element can be driven into a region separated from the surface of the semiconductor film (deep region) by performing the impurity element addition at a high acceleration energy as in Embodiment Mode 4. A region corresponding to the concentration peak of the p-type impurity element is formed in the deep region, and therefore depletion layer expansion can be suppressed, and the punch-through phenomenon can be effectively prevented.

Further, the formation of back channels can be suppressed by adding the impurity to element.

The silicon film is then patterned into a predetermined shape, forming semiconductor layers 106 to 109. Next, a gate insulating film 110 is formed covering the semiconductor layers 106 to 109. The gate insulating film 110 is formed from an insulating film containing silicon, at a thickness of 40 to 170 nm, using plasma CVD or sputtering. A silicon oxynitride film having a film thickness of 110 nm (composition ratios: Si=32%; O=59%; N=7%; and H=2%) is formed using plasma CVD in Embodiment Mode 4. The gate insulating film 110 is of course not limited to a silicon oxynitride film, and other insulating films containing silicon may also be used, in a single layer or a laminate structure. Further, if a silicon oxide film is used, it can be formed by using plasma CVD using a mixture of TEOS (tetraethyl orthosilicate) and O₂, at a reaction pressure of 40 Pa, with the substrate temperature set to 300 to 400° C., and by discharging at a high frequency (13.56 MHz) power density of 0.5 to 0.8 W/cm². Good characteristics as a gate insulating film can be obtained by subsequently performing thermal annealing of the silicon oxide film thus manufactured at a temperature of 400 to 500° C. (see FIG. 10D).

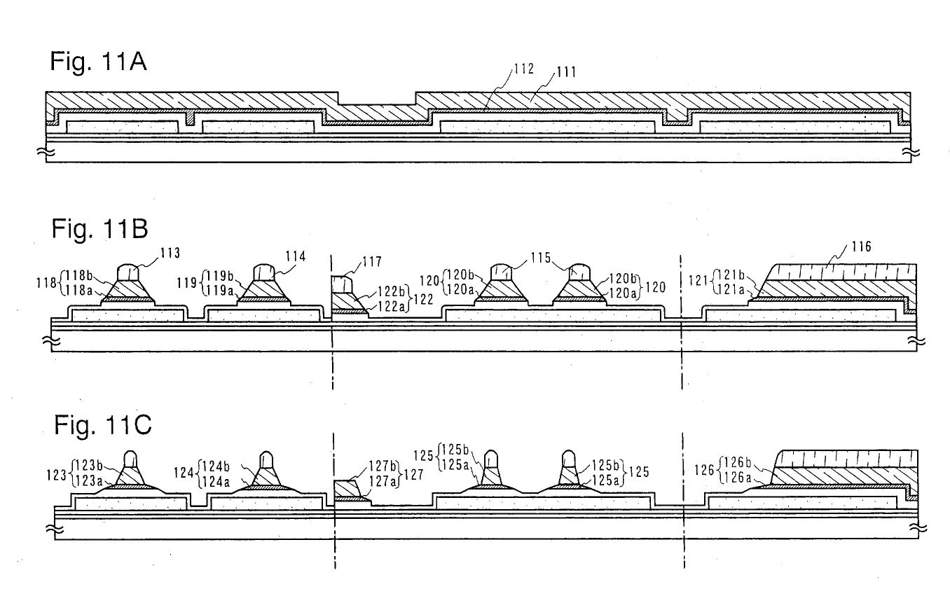

A conductive film is then formed on the gate insulating film 110 in order to form gate electrodes. A laminate is formed in Embodiment Mode 4 from TaN having a film thickness of 20 to 100 nm as a first conductive film 111, and W having a film thickness of 100 to 400 nm as a second conductive film 112. Note that, although the first conductive film 111 is TaN and the second conductive film 112 is W in Embodiment Mode 4, the conductive films are not limited to such films. There is no particular limitation thereon. The first conductive film 111 and the second conductive film 112 may each also be formed from an element selected from the group consisting of Ta, W, Ti, Mo, Al, Cu, Cr, and Nd, or from an alloy material or a compound material containing the element as its main constituent. Further, a semiconductor film, typically a polycrystalline silicon film, into which an impurity element such as phosphorous is doped may also be used as well as an AgPdCu alloy. Examples of combinations other than that used in Embodiment Mode 4 include: a combination of the first conductive film formed by using a tantalum (Ta) film and the second conductive film formed from a W film; a combination of the first conductive film formed by using a titanium nitride (TiN) film and the second conductive film formed from a W film; a combination of the first conductive film formed by a tantalum nitride (TaN) film and the second conductive film formed from a W film; a combination of the first conductive film formed by a tantalum nitride (TaN) film and the second conductive film formed from an Al film; and a combination of the first conductive film formed by using a tantalum nitride (TaN) film and the second conductive film formed from a Cu film. Furthermore, the structure is not limited to a two-layer structure, and a three-layer structure in which a tungsten film, and alloy film of aluminum and silicon (Al—Si), and a titanium nitride film are laminated in order may also be employed. If using a three-layer structure, tungsten nitride may also be used instead of tungsten, an alloy film of aluminum and titanium (Al—Ti) may also be used instead of the aluminum and silicon (Al—Si) alloy film, and a titanium film may also be used instead of the titanium nitride film. Note that it is essential to select suitably optimal etching methods and etchant types in accordance with the conductive film materials employed (see FIG. 11A).

Masks 113 to 117 made from resist are formed next using photolithography, and a first etching process is performed in order to form electrodes and wirings. The first etching process is performed under first and second etching conditions (see FIG. 11B). An ICP (inductively coupled plasma) etching method is used in Embodiment Mode 4 for the first etching conditions as follows: a gas mixture of CF₄, C1₂, and O₂ is used as an etching gas; the gas flow rates are set to 25:25:10 (sccm), respectively; and a plasma is generated by applying 500 W of RF power (13.56 MHz) to a coil shape electrode at a pressure of 1 Pa, after which etching is performed. 150 W of RF power (13.56 MHz) is also applied to the substrate side (sample stage), applying a substantially negative self-bias voltage. The W film is etched under the first etching conditions, and a tapered shape is formed in an edge portion of the first conductive layer.

The etching conditions are then changed to the second etching conditions, without removing the masks 113 to 117 made from resist. The second etching conditions are as follows: a gas mixture of CF₄ and Cl₂ is used as an etching gas; the gas flow rates are set to 30:30 (scem), respectively; and a plasma is generated by applying 500 W of RF power (13.56 MHz) to a coil shape electrode at a pressure of 1 Pa, after which etching is performed for approximately 30 seconds. 20 W of RF power (13.56 MHz) is also applied to the substrate side (sample stage), applying a substantially negative self-bias voltage. The W film and the TaN film are both etched on the same order under the second etching conditions, in which CF₄ and Cl₂ are mixed. Note that the etching time may also be increased by about 10 to 20% in order to perform etching without leaving any residue on the gate insulating film.

By using an appropriate shape for the masks made from resist in the first etching process, edge portions of the first conductive layer and the second conductive layer are formed in to tapered shapes due to the effect of the bias voltage applied to the substrate side. The angle of these tapered portions becomes from 15 to 45°. First shape conductive layers 118 to 122 (first conductive layers 118a to 122a and second conductive layers 118b to 122b) are thus formed from the first conductive layer 111 and the second conductive layer 112 by the first etching process. Regions of the gate insulating film 110 covered with no first shape conductive layers 118 to 122 are etched by about 20 to 50 nm, thus forming thin regions.

A second etching process is performed next without removing the masks made from resist (see FIG. 11C). The W film is selectively etched here using CF₄, Cl₂, and O₂ as etching gasses. Second conductive layers 123b to 127b are formed at this point by the second etching process. On the other hand, first conductive layers 123a to 127a are nearly unetched, and the shapes of the first conductive layers 123a to 127a remain almost unchanged from the first shape of first conductive layers 118a to 122a. Second shape conductive layers 123 to 127 are thus formed from the first conductive layers 123a to 127a, and the second conductive layers 123b to 127b.

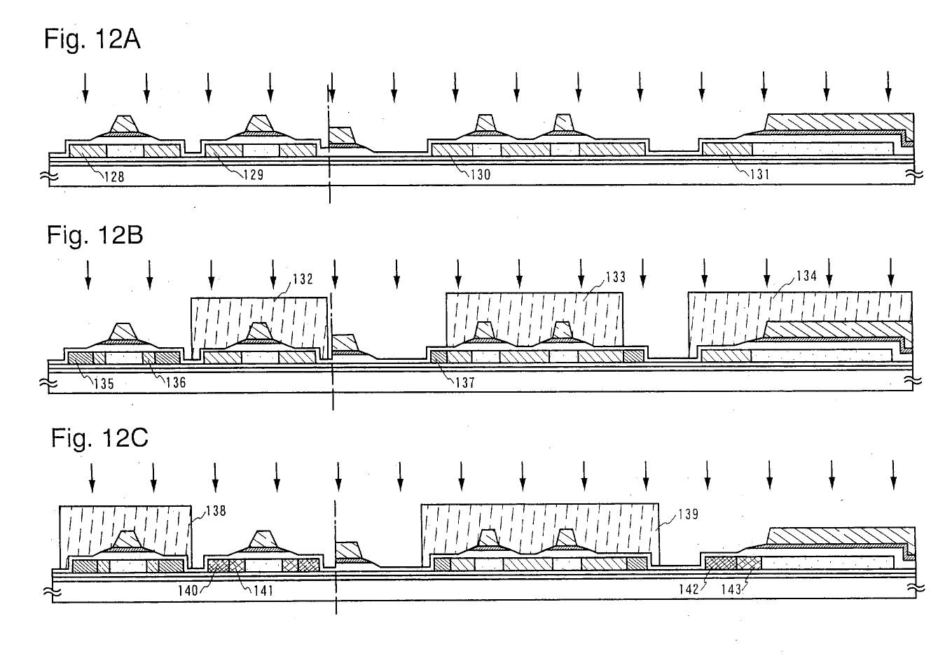

The resist masks are then removed, and a first doping process is performed. An impurity element that imparts n-type conductivity is added into islands at low concentration. A doping process may be performed by ion shower doping or ion injection. The ion shower doping method is performed under conditions in which the dosage is set to 1×10¹³ to 5×10¹⁴ /cm², and the acceleration energy is set to 40 to 80 keV. A dosage is set to 1.5×10¹³/cm² in Embodiment Mode 4, and doping is performed at an acceleration energy of 60 keV. An element belonging to Group 15 in the periodic table, typically phosphorous (P) or arsenic (As), is used as the impurity element that imparts n-type conductivity. Phosphorous (P) is used here. The conductive layers 123 to 127 become masks with respect to the impurity element that imparts n-type conductivity, and impurity regions 128 to 131 containing the n-type conductivity imparting impurity element at a concentration ranging from 1×10¹⁸ to 1×10²⁰/cm³ are formed in a self-alignment manner (see FIG. 12A).

Resist masks 132 to 134 are then formed, and a second doping process is performed at an acceleration energy higher than that used in the first doping process. Note that the resist mask 133 has a shape such that it covers the second shape conductive layer 125 on the semiconductor layer 108, and a portion of the semiconductor layer 108. Ion doping is performed under conditions in which the dosage is set to 1×10¹³ to 1×10¹⁷/cm², and the acceleration energy is set to 30 to 120 keV. The doping process is one in which an impurity element is added to the semiconductor layers under the tapered portion of the first conductive layers, using the second conductive layers 123b to 127b as masks against the impurity element. By the second doping process, an impurity element that imparts n-type conductivity is added to a low concentration impurity region 136, which overlaps with the first conductive layers, at a concentration range of 1×10¹⁸ to 5×10¹⁹/cm³. The impurity element that imparts n-type conductivity is added to high concentration impurity regions 135 and 137 at a concentration range of 1×10¹⁹ to 5×10²¹/cm³ (see FIG. 12B).

Although the low concentration impurity region and the high concentration impurity regions can be formed here by one doping process, it is needless to say that the doping process can be also divided into a plurality of doping processes and the regions are formed.

The masks made from resist are removed next, new masks 138 and 139 made from resist are formed, and a third doping process is performed. An impurity element that imparts a conductivity type which is opposite to the conductivity type of the aforementioned impurity element is added to semiconductor layers of p-channel TFTs by the third doping process, thus forming impurity regions 140 to 143. The impurity element that imparts p-type conductivity is added using the second conductive layers 123a to 127a as masks against the impurity element, thus forming the impurity regions in a self-alignment manner. The impurity regions 140 to 143 are formed by ion doping using diborane (B₂H₆) in Embodiment Mode 4 (see FIG. 12C). Although phosphorous is added to the impurity regions 140 to 143 at different concentrations by the first and the second doping processes, problems do not develop relating to the regions functioning as source regions and drain regions of the p-channel TFTs because the third doping process is performed so as to add the impurity element for imparting p-type conductivity at a concentration of 1×10¹⁹ to 5×10²¹ atoms/cm³ in each of the regions.

The impurity regions are thus formed in the respective semiconductor layer by the above processes.

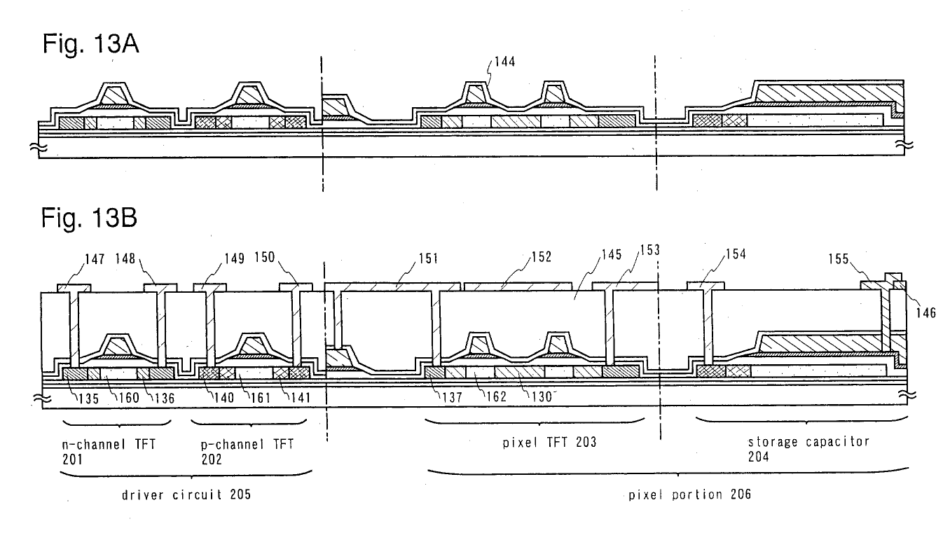

The resist masks 138 and 139 are removed next, and a first interlayer insulating film 144 is formed (see FIG. 13A). An insulating film containing silicon is formed at a thickness of 100 to 200 nm as the first interlayer insulating film 144 by using plasma CVD or sputtering. The silicon oxynitride film having a film thickness of 150 nm is formed in Embodiment Mode 4 by using plasma CVD. Of course the first interlayer insulating film 144 is not limited to a silicon oxynitride film, and other insulating films containing silicon may also be used, in single layer and laminate structures.

Laser irradiation is used next as a process for activating the impurity elements added to the semiconductor layers. It is possible to use the laser used during crystallization when employing laser annealing. The movement speed for activation is set to the same as during crystallization, and it becomes necessary to set the energy density to a value on the order of 0.01 to 100 MW/cm² (preferably from 0.01 to 10 MW/cm²). Further, a continuous wave laser may be used during crystallization, and a pulse oscillation laser may be used during activation.

The activation process may also be performed before forming the first interlayer insulating film.

Hydrogenation can then be performed if heat treatment is performed (thermal processing for 1 to 12 hours at 300 to 550° C.). This process is one of terminating dangling bonds in the islands by hydrogen contained in the first interlayer insulating film 144. Hydrogenation of the islands can be accomplished whether or not the first interlayer insulating film exists. Plasma hydrogenation (using hydrogen excited by a plasma), or heat treatment for 1 to 12 hours at 300 to 650° C. in an atmosphere containing 3 to 100% of hydrogen may also be used as other means of hydrogenation.

A second interlayer insulating film 145 made from an inorganic insulating film material or an organic insulator material is formed next on the first interlayer insulating film 144. An acrylic resin film having a film thickness of 1.6 μm is formed in Embodiment Mode 4.

Patterning is performed next in order to form contact holes reaching each of the impurity regions. A transparent conductive film is then formed at a thickness of 80 to 120 nm, and patterning is performed, thus forming a pixel electrode 142. An alloy of indium oxide and zinc oxide (In2O3—ZnO), and zinc oxide (ZnO) are materials suitable for use in the transparent conductive film. In addition, zinc oxide into which gallium (Ga) is added (ZnO:Ga) and the like can also be applied in order to increase the transmissivity of visible light or the conductivity.

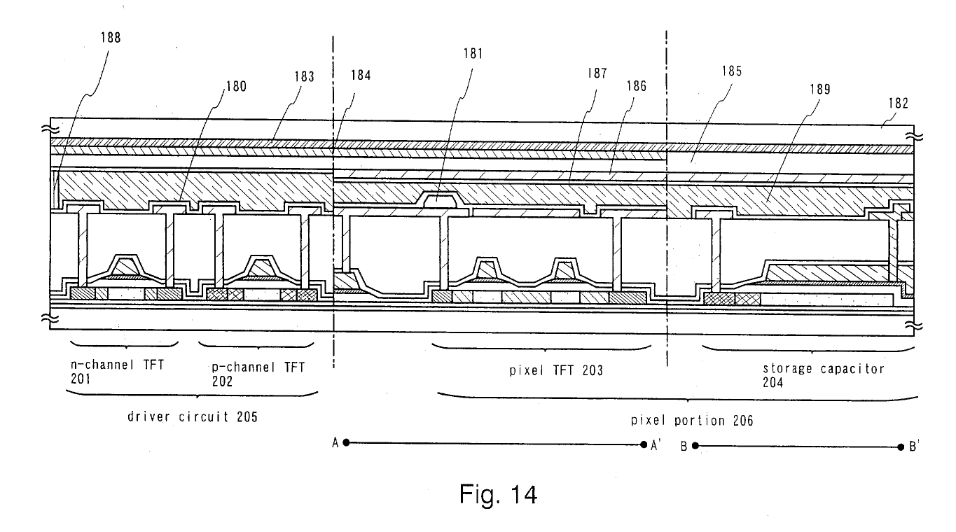

Wirings 147 to 150 for making electrical connections to each of the impurity regions are then formed in a driver circuit 205. Note that the wirings are formed by patterning a laminate film of a Ti film having a film thickness of 50 nm and an alloy film (alloy film of Al and Ti) having a film thickness of 500 nm. Needless to say, The wirings are not limited to a two-layer structure, and a single layer structure may also be used, and a laminate structure having three or more layers may also be used. Further, the wiring materials are not limited to Al and Ti. For example, a laminate film in which Al or Cu is deposited on a TaN film, and in addition, a Ti film is formed may be patterned, thus forming the wirings (see FIG. 14B).

Further, wirings 151 to 155 are formed in a pixel portion 206. A source wiring (laminate of the first conductive layer 127a and the second conductive layer 127b) is electrically connected to a pixel TFT 203 by the wiring 151. Furthermore, an electrical connection is formed between a pixel electrode 146 and the semiconductor layer 109, which functions as one electrode of a storage capacitor, through the wiring 155.

As described above, the driver circuit 205 having a CMOS circuit composed of an n-channel TFT 201 and a p-channel TFT 202, and the pixel portion 206 having the pixel TFT 203 and a storage capacitor element 204 can be thus formed on the same substrate. An active matrix substrate is thus completed.

The n-channel TFT 201 of the driver circuit 205 has a semiconductor layer having: a channel formation region 160; the low concentration impurity region 136 (GOLD region) overlapping with the first conductive layer 123a, which constitutes a portion of the gate electrode; and the high concentration impurity region 135, which functions as a source region or a drain region.

The p-channel TFT 202, which forms the CMOS circuit along with the n-channel TFT 201, has a semiconductor layer having: a channel formation region 161; the high concentration impurity region 140, which functions as a source region or a drain region; and the impurity region 141 into which a p-type impurity element of low concentration is introduced.

The pixel TFT 203 of the pixel portion 206 has a semiconductor layer having: a channel formation region 162; the low concentration impurity region 130; and the high concentration impurity region 137, which functions as a source region or a drain region.

Further, an impurity element that imparts n-type conductivity, and an impurity element that imparts p-type conductivity are added to the semiconductor layer 109, which functions as one electrode of the storage capacitor element 204. The storage capacitor element 204 is structured by an electrode (laminate of the first conductive layer 126a and the second conductive layer 126b) and the semiconductor layer, with the insulating film 110 used as a dielectric.

As described above, leak currents due to the punch-through phenomenon or the formation of back channels can be reduced, and the electrical characteristics of a TFT can be increased, by using the present invention and manufacturing a semiconductor device so that an impurity element (p-type impurity element for an n-channel TFT) is contained in a channel formation region at a concentration of 1×10¹⁵ to 5×10¹⁸/cm³, and a peak in the concentration of the impurity element is in a region at a depth equal to or greater than 60 nm from an interface between a semiconductor layer and a gate insulating film.

Further, a crystalline semiconductor film (crystalline silicon film) having a large crystal grain size can be formed by irradiating a CW laser to a semiconductor film (silicon film) for the semiconductor layer applied by Embodiment Mode 4, and therefore a high field effect mobility can be obtained, and a high performance semiconductor device capable of high speed operation can be realized.

Note that the present invention can be applied without any limitations placed on TFT shape. For example, it is possible to apply the present invention to bottom gate TFTs as well as the top gate TFTs as shown in FIG. 14.

### Embodiment Mode 5

An impurity element is added after the crystallization step of a semiconductor film in Embodiment Mode 4, but an example in which an impurity is added before the crystallization step is shown in Embodiment Mode 5.

The base insulating film 101 is formed on the substrate 100 in accordance with Embodiment Mode 4. The silicon film 102 is then formed by using a known means (such as sputtering, LPCVD, or plasma CVD) at a film thickness of about 60 to 400 nm on the base insulating film 101 as a semiconductor film. Note that the semiconductor film may be an amorphous semiconductor film, a microcrystalline semiconductor film, or a crystalline semiconductor film.

An impurity element that imparts p-type conductivity (p-type impurity element) is then added to the semiconductor film. Boron (B) is added as the p-type impurity element, for example, by using ion shower doping with an acceleration energy of 30 to 120 keV so that the actual concentration of the p-type impurity element within the silicon film 102 becomes 1×10¹⁵ to 5×10¹⁸/cm³. Note that, although the impurity element is added by using ion shower doping in Embodiment Mode 5, ion injection may also be applied as another method of adding the impurity.

Crystallization of the semiconductor film is then performed. A crystallization method in which continuous wave laser light is irradiated, similar to that disclosed by Embodiment Mode 4, may be applied as the crystallization method.

As described above, the value of leak currents can thus be reduced by the impurity elements contained in a channel formation region, even if the p-type impurity element is added to the semiconductor film before performing crystallization.

TFTs can then be formed by subsequent processing, in accordance with Embodiment Mode 3, to which a crystalline silicon film formed by Embodiment Mode 5 is applied.

Note that, although ion injection is used as the method of adding the impurity element to the semiconductor layer in Embodiment Modes 3 and 4, the semiconductor device containing the impurity element in the channel formation region may also be formed by performing film formation so as to include boron, for example, when forming the semiconductor film.

### Embodiment Mode 6

A method of forming a semiconductor film, in which an impurity element that imparts conductivity to the semiconductor film is added, is explained in Embodiment Mode 6. The formation of a silicon film, to which a p-type impurity element is added, by a process for forming the semiconductor film on a base insulating film is taken as an example.

The base insulating film 101 is formed on the substrate 100 in accordance with the processes of Embodiment Mode 4. A silicon film having added boron thereto is formed on the base insulating film 101 by using SiH₄, H₂, and B₂H₆/H₂ (B₂H₆ and H₂ introduced into one gas cylinder) as material gasses. The substrate temperature is set to 300° C., the pressure to 99.75 Pa, the power to 20 W, and the gap between electrodes to 30 mm.

For example, a silicon film containing boron (B) therein at a concentration of 3×10¹⁷/cm³ can be formed by performing film formation for the silicon film under the above-mentioned conditions, with the relative gas flow rates of SiH₄, H₂, and B₂H₆/H₂ set to 50/49/15 sccm, respectively.

As described above, the silicon film having added boron thereto at a concentration of 1×10¹⁵ to 5×10¹⁸/cm³ can thus be formed by using CVD.

It is possible to make a semiconductor device in accordance with the processes disclosed in Embodiment Mode 4 by using the silicon film thus obtained.

### Embodiment Mode 7

The process of manufacturing an active matrix liquid crystal display device (also referred to as a liquid crystal display panel) from an active matrix substrate manufactured by applying Embodiment Modes 4 to 6 is explained in Embodiment Mode 7. FIG. 14 is used in the explanation.

First, an active matrix substrate having the state of FIG. 13B is obtained in accordance with Embodiment Mode 4, after which an orientation film 180 is formed on the active matrix substrate of FIG. 13B, and a rubbing process is performed. Note that columnar spacers 181 are formed at predetermined locations by patterning an organic resin film, such as an acrylic resin film, before forming the orientation film 180 in Embodiment Mode 7 in order to maintain a substrate gap. Further, spherical spacers may also be dispersed over the entire substrate as a substitute for the columnar spacers.

An opposing substrate 182 is prepared next. Colored layers 183 and 185, and a leveling film 185 are formed on the opposing substrate. Portions of the red colored layer 183 and the blue colored layer 184 overlap, thus forming a second light-shielding portion. Note that, although not shown in FIGS. 13A and 13B, portions of the red colored layer and a green colored layer also overlap, forming a first light-shielding portion.

An opposing electrode 186 is then formed in a pixel portion, and an orientation film 187 is formed over the entire surface of the opposing substrate, and a rubbing process is performed.

The active matrix substrate on which the pixel portion and driver circuits are formed is then bonded to the opposing substrate by using a sealing member 188. A filler is mixed into the sealing member 188, and the two substrates are bonded together while maintaining a uniform gap by the filler and the columnar spacers. A liquid crystal material 189 is next injected between the two substrates, and complete sealing is performed by using a sealant (not shown in the figure). Known liquid crystal materials may be used as the liquid crystal material 189. The active matrix liquid crystal display device shown in FIG. 14 is thus completed. The active matrix substrate or the opposing substrate may then be sectioned into a predetermined shape if necessary. In addition, polarization plates and the like may be suitably formed by using known techniques. An FPC may also be attached by using a known technique.

The liquid crystal display panel thus manufactured can be used as a display portion for various types of electrical appliances.

### Embodiment Mode 8

Another embodiment of forming a crystalline semiconductor film (crystalline silicon film) is shown in Embodiment Mode 8.

A metallic element is added to a semiconductor film with an objective of lowering the crystallization temperature and promoting crystal growth. Single element or a mixture of a plurality of elements selected from the group consisting of Fe, Co, Ni, Ru, Rh, Pd, Os, Ir, Pt, Cu, and Au is known as an applicable metallic element. Ni is typically applied, and an aqueous solution containing 5 ppm of nickel acetate salt is applied by spin coating in order to add Ni, thus forming a catalytic element containing layer 501. Needless to say, the metallic element addition method is not limited to spin coating, and various substitute means, such as evaporation and sputtering, may also be applied.

Dehydrogenation processing is performed next for one hour at 500° C., and heat treatment is performed for 4 to 12 hours at 550° C., thus crystallizing an amorphous silicon film. Crystallization is such that suicides are formed and diffuse within the amorphous silicon film by the action of Ni, and crystal growth occurs at the same time. A crystalline silicon film 502 thus formed comprises aggregations of rod shape or needle shape crystals. Each of the crystals grows having a specific macroscopic orientation, and therefore the crystallinity is aligned. Furthermore, the orientation ratio for the (110) plane is high as characteristics thereof.

Melting is then performed by irradiating continuous wave laser light (CW laser light) 503, forming a melted phase. The melted phase is moved continuously by scanning the irradiation position of the laser light 503, thus forming a crystalline silicon film 504 having increased crystallinity. Crystal growth occurs by this process such that the crystal grains extend in the scanning direction of the laser light. A crystalline silicon film in which the crystal planes are aligned is formed in advance in this case, and therefore crystal precipitates of different planes can be prevented, and the generation of dislocations can also be prevented.

It is possible to add an impurity element as shown in Embodiment Mode 4 to the crystalline semiconductor film (crystalline silicon film) thus obtained in Embodiment Mode 8, and it is possible to manufacture a semiconductor device by subsequent processing in accordance with Embodiment Mode 4. Furthermore, TFTs may also be manufactured by applying the crystallization method disclosed in Embodiment Mode 8 after adding the impurity element.

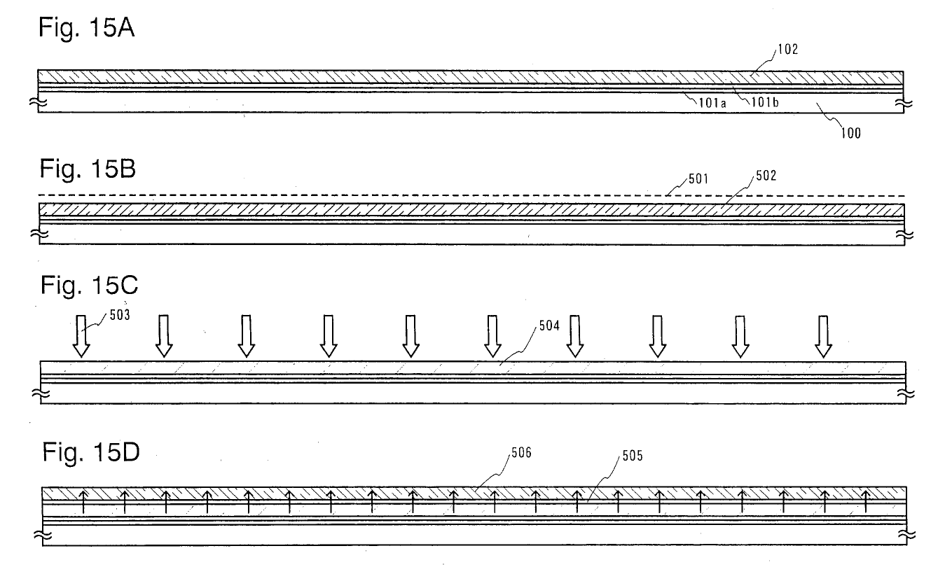

Note that, if a catalytic element like that disclosed in Embodiment Mode 8 is added, it is preferable to perform gettering in order to remove the catalytic element, or reduce its concentration, contained in the semiconductor film (silicon film), which becomes an element region after completing the crystallization process, so that there is no adverse influence on the electrical characteristics. Known methods may be applied as the gettering process. Further, a method may also be employed, in which a barrier layer 505 made from a thin silicon oxide film is formed on the crystalline silicon film 504 as shown in FIG. 15D, a gettering region made from an amorphous silicon film, to which argon or phosphorous is added at a concentration of 1×10²⁰/cm³ to 1×10²¹/cm³, is formed as a gettering site 506 on the barrier layer 505 by sputtering, and heat treatment is performed, thus moving the catalytic element to the gettering region.

The catalytic element can be removed by performing the above-mentioned gettering process. In addition, distortions can also be relieved and the density of defects can also be reduced.

Embodiment Mode 8 can be applied together with any of Embodiment Modes 4 to 7.

### Embodiment Mode 9

An n-channel TFT is explained in Embodiment Modes 4 and 5, and a p-channel TFT is explained in Embodiment Mode 9.

For cases in which there is a desire to reduce the leak current in a p-channel TFT, an n-type impurity element, for example, phosphorous may be added to a channel formation region at a concentration of 1×10¹⁵ to 5×10¹⁸/cm³ contrary to an n-channel TFT.

For cases in which an n-channel TFT and a p-channel TFT are formed on the same substrate, and boron is added to a region that later becomes an n-channel TFT, a p-type impurity element (typically boron) may be added after forming a mask in a region which later becomes a p-channel TFT. Conversely, if an n-type impurity element is added to a region that becomes a p-channel TFT, then an n-type impurity element (typically phosphorous) may be added after masking a region which later becomes an n-channel TFT.

Note that a process for adding an n-type impurity element at a low concentration, on the order of 1×10¹⁵ to 5×10¹⁸/cm³, to a region that becomes a p-channel TFT may be performed after crystallizing the semiconductor film, as disclosed in Embodiment Mode 4, and may also be performed before the crystallization process, as disclosed by in Embodiment Mode 5.

Embodiment Mode 9 can be applied in combination with Embodiment Mode 4 or Embodiment Mode 5.

### Embodiment Mode 10

A CMOS circuit and a pixel portion formed by carrying out the present invention can be used in an active matrix liquid crystal display (liquid crystal display device). That is, the present invention can be applied to all the electrical appliances which install the liquid crystal display devices in the display portions.

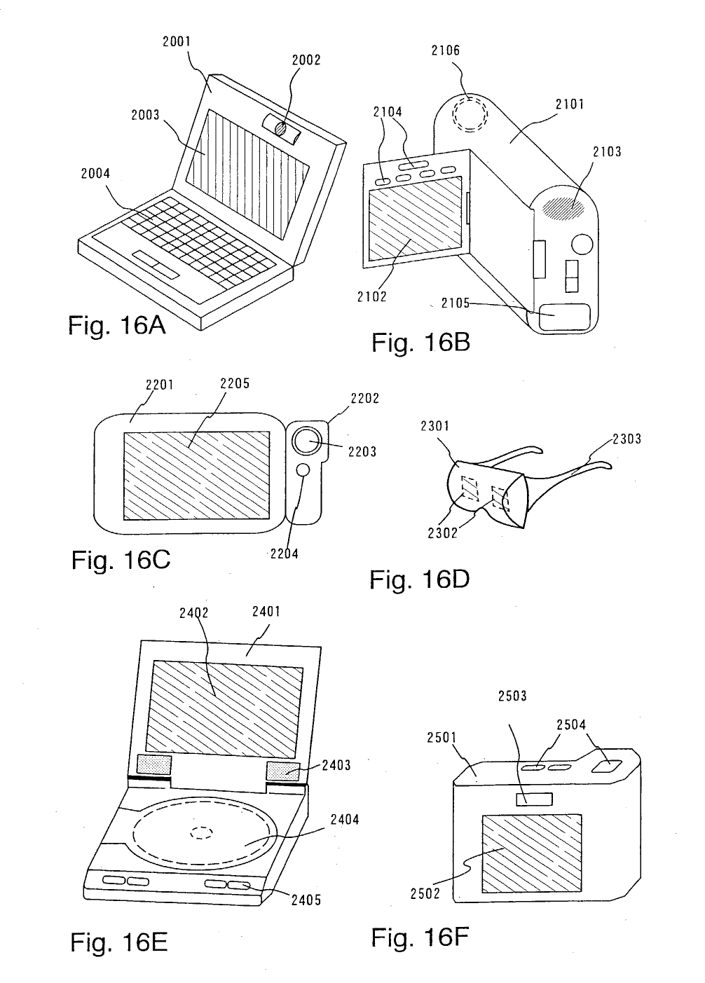

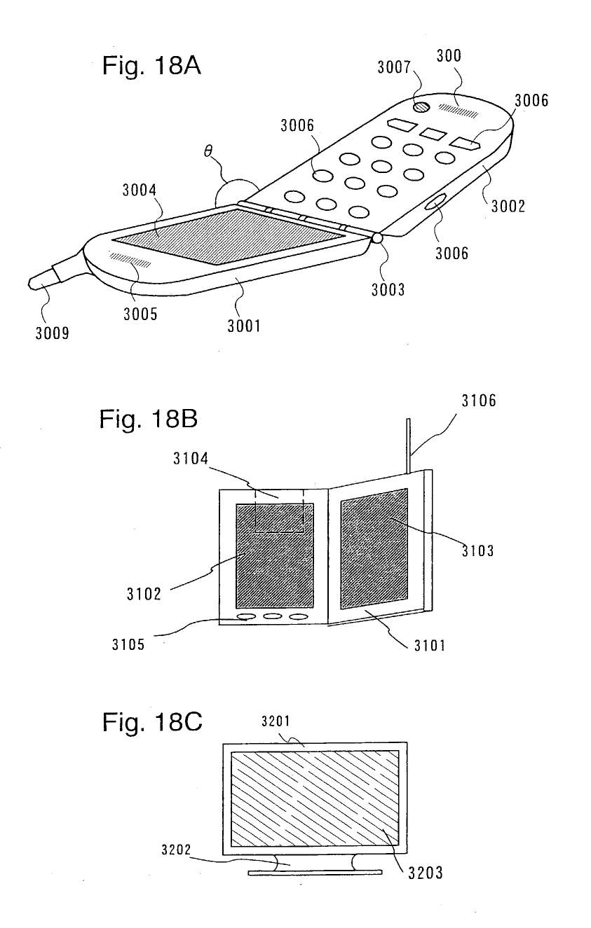

Examples of such electrical appliances may include, video cameras, digital cameras, projectors (rear and front types), head mounted displays (goggle type displays), personal computers, and portable information terminals (mobile computers, mobile phones, electronic book, or the like). An example of such appliances is shown in FIGS. 16A and 18C.

FIG. 16A shows a personal computer, which is composed of a main body 2001, an image input portion 2002, a display portion 2003, a keyboard 2004, and the like.

FIG. 16B shows a video camera, which is composed of a main body 2101, a display portion 2102, a voice input portion 2103, operational switches 2104, a battery 2105, an image receiving portion 2106, and the like.

FIG. 16C shows a mobile computer, which is composed of a main body 2201, a camera portion 2202, an image receiving portion 2203, operational switches 2204, a display portion 2205, and the like.

FIG. 16D shows a goggle type display, which is composed of a main body 2301, a display portion 2302 an arm portion 2303, and the like.

FIG. 16E shows a player using a recording medium having a program recorded thereon (hereinafter referred to as a recording medium), which is composed of a main body 2401, a display portion 2402, a speaker portion 2403, a recording medium 2404, operational switches 2405, and the like. Note that the player uses media such as DVDs (digital versatile discs) and CDs as the recording media, and can be used for music appreciation, film appreciation, games, and accessing the Internet.

FIG. 16F shows a digital camera, which is composed of a main body 2501, a display portion 2502, a viewfinder 2503, operational switches 2504, an image receiving portion (not shown in the figure), and the like.

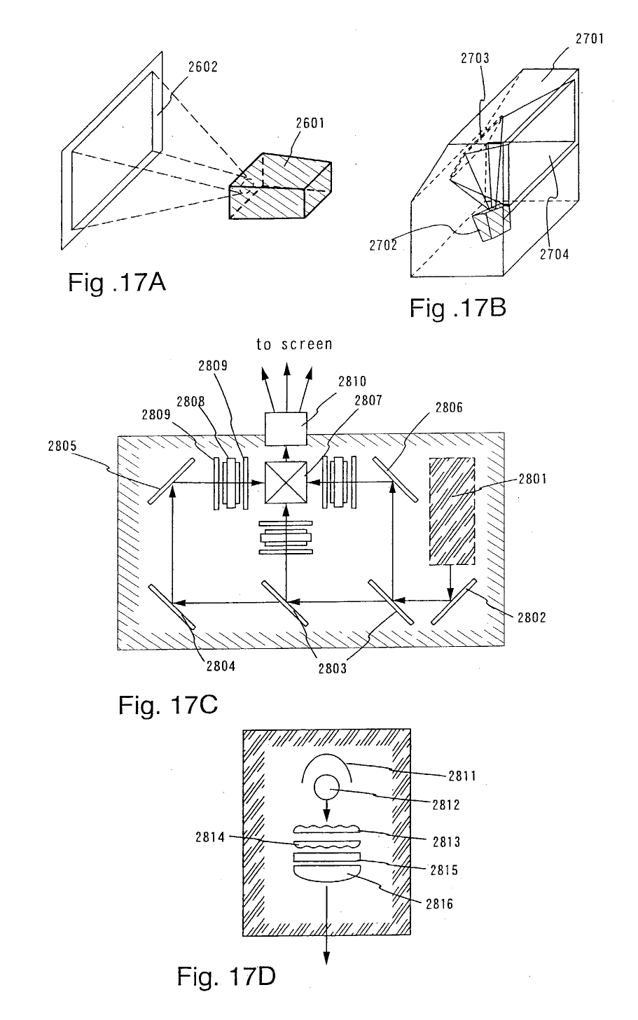

FIG. 17A shows a front type projector, which is composed of a projection device 2601, a screen 2602, and the like.

FIG. 17B shows a rear type projector, which is composed of a main body 2701, a projection device 2702, a mirror 2703, a screen 2704, and the like.

Note that, FIG. 17C is a view showing an example of structures of the projection devices 2601 and 2702 in FIGS. 17A and 17B. The projection devices 2601 and 2702 are composed of a light source optical system 2801, mirrors 2802 and 2804 to 2806, dichroic mirrors 2803, a prism 2807, a liquid crystal display device 2803, a phase difference plate 2809, and a projection optical system 2810. The projection optical system 2810 is constituted of an optical system including a projection lens. In Embodiment Mode 10, a 3-CCD type is shown by way of example, but there is put no particular limitation thereon. For example, a single-CCD type may be employed. Also, the performer may appropriately provide, in some midpoint of an optical path indicated by the arrow of FIG. 17C, an optical system such as an optical lens, a film having a polarization function, a film for adjusting a phase difference, or an IR film.

Further, FIG. 17D is a view showing an example of a structure of the light source optical system 2801 shown in FIG. 17C. In Embodiment Mode 10, the light source optical system 2801 is constituted of a reflector 2811, a light source 2812, lens arrays 2813, 2814, a polarization conversion element 2815, and a condensing lens 2816. Note that, the light source optical system shown in FIG. 17D is only employed as an example, and there is put no particular limitation thereon. For example, the performer may appropriately provide in the light source optical system the optical system such as the optical lens, the film having a polarization function, the film for adjusting a phase difference, or the IR film.

However, in the projector shown in FIGS. 17A to 17D, a transmissive type electro-optical device is used, and an example in which a reflective type liquid crystal display device is used is not shown in the figures.

FIG. 18A shows a mobile phone, which is composed of a display panel 3001 and an operation panel 3002. The display panel 3001 and the operation panel 3002 are connected through a connection portion 3003, in which angle θ between a plane in which a display portion 3004 of the display panel 3001 is formed and a plane in which operational keys 3006 of the operation panel 3002 are formed can be arbitrarily changed.

Further, the mobile phone includes a voice output portion 3005, the operational keys 3006, a power supply switch 3007, and a voice input portion 3008.

FIG. 18B shows a portable book (electronic book), which is composed of a main body 3101, display portions 3102, 3103, a recording medium 3104, operational switches 3105, an antenna 3106, and the like.

FIG. 18C shows a display, which is composed of a main body 3201, a support stand 3202, a display portion 3203, and the like. The display of the present invention is particularly advantageous when used in enlarged screens, such as displays with 10 or more inches diagonally (especially 30 or more inches).

As mentioned above, the applicable range of this invention is very wide, and it is possible to apply it to electrical appliances of all fields.

Depletion layer expansion can be suppressed by adding an impurity element that imparts p-type conductivity to a channel formation region of an n-channel TFT, for example, and leak currents flowing when a TFT is off can be reduced, in accordance with the present invention. Further, leak currents flowing when the TFT is off, which develop due to the formation of back channels, can be suppressed.

A good quality crystalline semiconductor film (crystalline silicon film) having large crystal grain size can be formed by applying the present invention, and therefore a high field effect mobility can be obtained for TFTs manufactured by applying this type of semiconductor film. Further, it becomes possible to realize system on panel, system on glass, or sheet computer in which a video display region, driver circuits for the image display region, and in addition, a microprocessor memory, etc. are mounted in combination and integrated, by using the above-mentioned TFTs.

What is claimed is:

1. A semiconductor device comprising:
a semiconductor film on an insulating surface;
a gate insulating film over the semiconductor layer; and
a gate electrode over the gate insulating film,
wherein:
the semiconductor film comprises at least a channel formation region, a source region, and a drain region;
the channel formation region contains an impurity element at a concentration of 1×10¹⁵ to 5×10¹⁸/cm³;
a film thickness of the channel formation region is equal to or greater than 60 nm; and
a concentration peak of the impurity element is set to a region at a depth equal to or greater than 60 nm from a surface of the channel formation region.

2. A semiconductor device according to claim 1, wherein:
the impurity element contained in the channel formation region is an impurity element that imparts a p-type conductivity in a case of a channel formation region of an n-channel TFT.

3. A semiconductor device according to claim 1, wherein:
the impurity element contained in the channel formation region is an impurity element that imparts an n-type conductivity in a case of a channel formation region of a p-channel TFT.

4. A semiconductor device according to claim 1, wherein:
a thickness of the semiconductor film is equal to or less than 200 nm.

5. A method of manufacturing a semiconductor device, comprising:
forming a semiconductor film having a thickness equal to or greater than 60 nm;
irradiating continuous wave laser to the semiconductor film to form an interface between a melted phase and a solid phase to form a crystalline semiconductor film; and
adding an impurity element to the crystalline semiconductor film,
wherein:
the impurity element is added so that a position of a concentration peak of the impurity element is at a depth equal to or greater than 60 nm in a depth direction of the crystalline semiconductor film.

6. A method of manufacturing a semiconductor device, comprising:
forming a semiconductor film having a thickness equal to or greater than 60 nm;
adding an impurity element to the semiconductor film; and
irradiating continuous wave laser to the semiconductor film to form an interface between a melted phase and a solid phase to form a crystalline semiconductor film,
wherein:
the impurity element is added so that a position of a concentration peak of the impurity element is at a depth equal to or greater than 60 nm in a depth direction of the crystalline semiconductor film.

7. A method of manufacturing a semiconductor device according to claim 5, wherein:
the addition of the impurity element is performed by an ion shower doping method, at an acceleration energy equal to or greater than 30 keV.

8. A method of manufacturing a semiconductor device according to claim 6, wherein:
the addition of the impurity element is performed by an ion shower doping method, at an acceleration energy equal to or greater than 30 keV.

9. A method of manufacturing a semiconductor device according to claim 7 wherein:
the acceleration energy is equal to or less than 120 keV.

10. A method of manufacturing a semiconductor device according to claim 8 wherein:
the acceleration energy is equal to or less than 120 keV.

11. A method of manufacturing a semiconductor device according to claim 7 wherein:
the acceleration energy is equal to or less than 80 keV.

12. A method of manufacturing a semiconductor device according to claim 8 wherein:
the acceleration energy is equal to or less than 80 keV.

13. A method of manufacturing a semiconductor device according to claim 5, wherein:
the laser uses a solid laser oscillating apparatus as a light source, which is a second harmonic of an Nd:YAG laser, an Nd:YVO₄ laser, an Nd:YLF laser, a Ti:sapphire laser, or an alexandrite laser.

14. A method of manufacturing a semiconductor device according to claim 6, wherein:
the laser uses a solid laser oscillating apparatus as a light source, which is a second harmonic of an Nd:YAG laser, an Nd:YVO₄ laser, an Nd:YLF laser, a Ti:sapphire laser, or an alexandrite laser.

15. A semiconductor device according to claim 1, wherein the semiconductor device is applied to an electrical appliance selected from the group consisting of a video camera, a digital camera, a projector, a head mounted display, a personal computer, a mobile computer, a mobile phone and an electronic book.

16. A method of manufacturing a semiconductor device according to claim 5, wherein the semiconductor device is applied to an electrical appliance selected from the group consisting of a video camera, a digital camera, a projector, a head mounted display, a personal computer, a mobile computer, a mobile phone and an electronic book.

17. A method of manufacturing a semiconductor device according to claim 6, wherein the semiconductor device is applied to an electrical appliance selected from the group consisting of a video camera, a digital camera, a projector, a head mounted display, a personal computer, a mobile computer, a mobile phone and an electronic book.
